(19) United States
(12) Patent Application Publication
(10) Pub. No.: US 2023/0006049 A1
(43) Pub. Date: Jan. 5, 2023

(54) SILICON CARBIDE POWER DEVICE WITH AN ENHANCED JUNCTION FIELD EFFECT TRANSISTOR REGION

(71) Applicant: Hunan Sanan Semiconductor Co., Ltd., Hunan (CN)

(72) Inventor: Mrinal Kanti Das, Allen, TX (US)

(21) Appl. No.: 17/363,218

(22) Filed: Jun. 30, 2021

(51) Int. Cl. H01L 29/423; H01L 29/16; H01L 29/78; H01L 29/10; H01L 29/66

(52) U.S. Cl. CPC H01L 29/42368; H01L 29/1608; H01L 29/7802; H01L 29/1033; H01L 29/66068

(57) ABSTRACT

A semiconductor device includes a body, a gate oxide layer, and a gate electrode. The body is defined by a drift region and one or more implant regions. A junction field effect region is defined between one of the implant regions and another one of the implant regions. The gate oxide layer is grown as a single, unitary structure extending across the semiconductor body and at least partially overlap the implant regions. The gate oxide layer is additionally defined by a central expansion region between the implant regions, and extend into the junction field effect region. A gate electrode is disposed on the gate oxide layer.

### CROSS-REFERENCE TO RELATED APPLICATIONS

Not Applicable

### STATEMENT RE: FEDERALLY SPONSORED RESEARCH/DEVELOPMENT

Not Applicable

### BACKGROUND

### 1. Technical Field

The present disclosure relates generally to semiconductors and transistor structures, and more particularly, to a silicon carbide (SiC) power device with enhanced junction field effect transistor (JFET) region.

### 2. Related Art

The metal oxide semiconductor field effect transistor (MOSFET) is a foundational component of modern electronics, and variants specific to different application requirements have been developed. One such variant is the power MOSFET, which is capable of handling the high power levels necessary for switching and rectification in power circuits, among other applications. Power MOSFETs most commonly have a vertical structure that is comprised of a semiconductor substrate with the source and gate contacts disposed above the substrate and the drain contact disposed beneath the substrate. Silicon carbide (SiC) is utilized for the substrate as well as the epitaxial layer in power MOSFETs because of its superior properties, including wide-bandgap, high electric breakdown field, high thermal conductivity, higher saturation electron drift velocity, and radiation immunity. The resultant semiconductor devices can operate at higher temperatures, voltages, and frequencies.

The structure of the power MOSFET is further defined by a drift layer that is formed over the substrate, which has one doping type, e.g., an N-type. Furthermore, in a multiple implantation process, one or more wells of the opposite doping type, e.g., a P-type or P-well is implanted into the substrate, along with an N-region that is further implanted into the P-well. The P-well and the N-region, which may also be more generally referred to as the source region, are spaced apart from each other, with the area between each being referred to as a junction field effect transistor (JFET) region. Source contacts are formed over the source regions, while a gate oxide layer is formed on the drift layer between the source regions. A gate electrode is then added on to the gate oxide layer, which spans only a portion thereof.

Each of the foregoing elements of the vertical MOSFET structure have associated resistances that contribute to the overall resistance between the drain and source contacts, some of which are desirable and some of which are parasitic. It is understood that in a conventional 1200V silicon carbide device, channel resistance (R_{ch}) accounts for approximately 43% of the overall resistance, while the JFET resistance (R_{JFET}) accounts for approximately 24% of the overall resistance. Additionally, there may be a source resistance (R_{source}), contact resistance (R_{contact}), and substrate resistance (R_{sub}), which account for approximately 5%, 2%, and 10%, respectively. The overall resistance also includes a drift region resistance R_{drift}, which is non-parasitic and sets the blocking voltage of the power MOSFET.

With the JFET resistance representing a substantial proportion of the overall resistance and second only to the channel resistance, there is a need in the art for its reduction for improved performance and reliability. One approach that has been taken to reduce channel resistance is increasing the size of the JFET region, that is, increasing the separation distance between the adjacent p-wells. There are understood to be certain tradeoffs with this approach, however. For instance, the larger JFET gap may increase the unit cell pitch, and thus reduces the packing density of the device. Furthermore, a larger electric field may be present at the center of the JFET region, thereby placing additional stress on the gate oxide. Although silicon carbide can support electric fields in excess of 2 MV/cm, conventional practice sets limits of under 1.6 MV/cm so that the corresponding gate oxide electric field is maintained below 4 MV/cm. The SiO₂ gate oxide may begin to break down at 10 MV/cm, but in order to ensure device longevity, the electric field is maintained at such lower levels. Accordingly, there are practical limits to the width of the JFET region.

Another known approach for reducing channel resistance involves increasing the doping of the JFET region. This is understood to reduce the depletion effects of the adjacent P-wells, and result in a reduced JFET resistance. Like the first approach of increasing the size of the JFET region discussed above, tradeoffs are associated with this second approach. The increased JFET doping causes a substantial increase in the substrate (SiC) electric field, and a corresponding increase in the gate oxide electric field. Again, conventionally, the gate oxide electric field is limited to less than 4 MV/cm, which results in the SiC electric field being less than 1.6 MV/cm. This may be counteracted to a certain extent with a thicker gate oxide, but which results in the resistance in the channel region, that is, the surface of the P-well.

There is thus a need in the art for a simplified method for fabricating an improved silicon carbide power MOSFET with an enhanced JFET region with reduced resistance.

### BRIEF SUMMARY

The embodiments of the present disclosure contemplate improvements over conventional metal oxide semiconductor field effect devices that mitigate oxide electric field limitations. This may be achieved by selectively increasing the thickness of the oxide layer within the junction field effect transistor (JFET) region to suppress the oxide electric field, while retaining reduced thickness in the channel region to maintain low channel resistance.

One embodiment is a power metal oxide semiconductor field effect device that may include a first semiconductor type body that is defined by a drift region, one or more second semiconductor type implants, and one or more first semiconductor type implant implants within corresponding ones of the one or more second semiconductor type implants. There may be a junction field effect region that is defined between a given set of the first semiconductor type implant and the second semiconductor type implant and another set of the first semiconductor type implant and the second semiconductor type implant. The device may also include a gate oxide layer that spans a top surface of the semiconductor body across one set of the first and second semiconductor type implants and another set of the first and second semiconductor type implants. Channel regions may be defined at interfaces of the gate oxide layer and the sets of the first and second semiconductor type implants. The gate oxide layer may further define a central expansion region between the sets of the first and second semiconductor type implants. The gate oxide layer may also extend into the junction field effect region. The device may further include a gate electrode disposed on the gate oxide layer, a source electrode at least partially overlapping the first semiconductor type implants and the second semiconductor type implants, and a drain electrode that is disposed underneath the semiconductor body.

Another embodiment of the present disclosure is a semiconductor device with at least a body, a gate oxide layer, and a gate electrode. The body may be defined by a drift region and one or more implant regions. Further, there may be a junction field effect region that is defined between one of the implant regions and another one of the implant regions. The gate oxide layer may be grown as a single, unitary structure extending across the semiconductor body and at least partially overlapping the implant regions. The gate oxide layer may further define a central expansion region between the implant regions and extend into the junction field effect region. The device may additionally include a gate electrode that is disposed on the gate oxide layer.

The present disclosure also contemplates a method for fabricating a power metal oxide semiconductor field effect device. The method may begin with a precursor step of fabricating a semiconductor substrate with a body defined by a drift region, one or more implant regions, and a junction field effect region between one of the implant regions and another one of the implant regions. Next, the method may proceed to a step of patterning a central expansion region into a center of the junction field effect region. There may also be a step of implanting an ionic species into the central expansion region. The method may further include forming a gate oxide layer above a top layer of the semiconductor substrate by thermal oxidation. This may be a single formation step without annealing the implanted ionic species. The gate oxide layer may extend into the junction field effect region and define the central expansion region and channel regions peripheral thereto. The method may also include forming a gate electrode over the gate oxide layer.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a cross-sectional view of a conventional power metal oxide semiconductor field effect transistor (MOSFET);

FIG. 2A is a cross-sectional view of a power MOSFET in accordance with one embodiment of the present disclosure;

FIG. 2B is a cross-sectional view of a power MOSFET in accordance with another embodiment of the present disclosure;

FIG. 3 is another cross-sectional view of the power MOSFET of the present disclosure illustrating the dimensional specifics thereof;

FIG. 4A-4C show cross-sectional views at various fabrication steps of the power MOSFET according to the present disclosure; and

FIG. 5 is a flowchart describing the fabrication steps of the power MOSFET.

### DETAILED DESCRIPTION

The detailed description set forth below in connection with the appended drawings is intended as a description of the several presently contemplated embodiments of a silicon carbide power device with an enhanced junction field effect region and is not intended to represent the only form in which such embodiments may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second, upper and lower, and the like are used solely to distinguish one from another entity without necessarily requiring or implying any actual such relationship or order between such entities. Similarly, relative terms such over, above, under, horizontal, vertical, and so on are also used to describe a positional relationship between one feature and another in the particularly illustrated orientation. Alternatively presented orientations may be described with corresponding relative terms, and such alternatives are deemed to be within the purview of those having ordinary skill in the art.

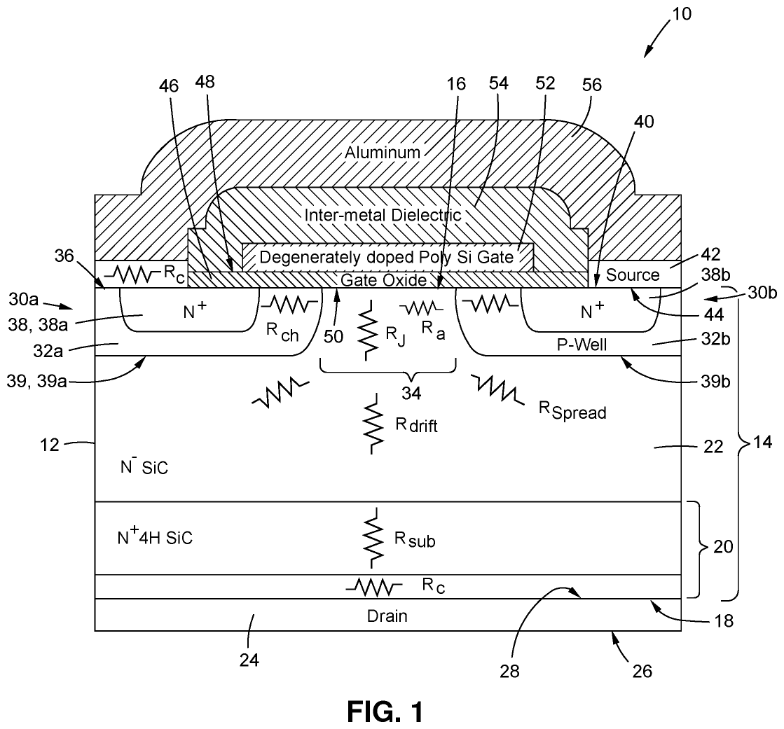

FIG. 1 illustrates a conventional power MOSFET (metal oxide semiconductor field effect transistor) 10, which is generally defined by a semiconductor substrate 12, along with various layers above and underneath the same and different regions within the semiconductor substrate 12 as will be described in further detail as follows. As is preferred for high powered devices, the semiconductor substrate 12 is a silicon carbide (SiC) material. Numerous polytypes of SiC are known in the art and have varying properties that make one polytype more suitable for certain applications than others. One common polytype selected for high powered semiconductor applications is 4H, though any other polytype may be selected.

The semiconductor substrate 12 may be defined as a body 14 with a body top surface 16 and an opposed body bottom surface 18. The depicted MOSFET is an N-type device, and thus the semiconductor substrate 12 is doped with an N-type doping impurity. Certain embodiments of the present disclosure may generally refer to this as a first type doping impurity, though it is not intended to explicitly associate the first type dopant as an N-type. To the extent an alternative implementation is a P-type device, the first type dopant may be a P-type. Thus, reference to a first type doping impurity or a second type doping impurity is not to be limiting.

The body 14 may be generally characterized by a highly N⁺ doped substrate region 20, along with a lightly N⁻ doped drift region 22 or epitaxial layer over the substrate region 20. As a vertically oriented semiconductor device, a drain electrode 24 is disposed underneath the semiconductor substrate 12. The drain electrode 24 is defined by a drain electrode bottom surface 26 that coincides with the bottom surface of the MOSFET 10 overall, and an opposed drain electrode bottom surface 28 that faces and abuts against the body bottom surface 18. The interface between the substrate region 20 and the drain electrode 24 has an associated contact resistance R_{c}, while the substrate region 20 has an associated resistance Rₛᵤb. Along these lines, the drift region 22 is understood to have a resistance R_{drift}.

The cross-sectional view of FIG. 1 is of a single cell of the MOSFET 10 bounded by a left side 30a and an opposed right side 30b, but such boundaries are arbitrary, and in a physical implementation, they may be characterized by any number of possible shapes. The straight side walls are thus presented by way of example only and not of limitation. On the left side 30a, the body 14 may include a P-well 32a, while the opposite right side 30b may include a P-well 32b. The P-wells 32 extend downwardly into the body 14 and specifically the drift region 22 thereof. The P-wells 32 are understood to be areas in the semiconductor substrate 12 that is implanted with a P-type doping impurity. In the context of the implementation in which the semiconductor substrate 12 is an N-type doping impurity and referred to as a first type doping impurity, the P-type doping impurity in the P-well 32 may be referred to as a second type doping impurity.

The P-well 32a on the left side 30a is separated from the P-well 32b on the right side 30b by a junction field effect (JFET) region 34. The particular boundaries between where the P-type doping impurity is implanted and the areas generally constituting the drift region 22 and the JFET region 34 may be somewhat varied. As such, the JFET region 34 may be referred to broadly as the area between the P-wells 32a and 32b. The upper boundary of the P-wells 32, on the other hand, coincide with the body top surface 16. Those parts of the body top surface 16 implanted with the second or P-type impurities may be referred to as a P-well top surface 36. The JFET region 34 is understood to define a JFET resistance, R_{JFET}, which is reduced in accordance with the embodiments of the present disclosure.

There is a source implant 38 within each of the P-wells 32. More particularly, in the first P-well 32a there is a first source implant 38a, and in the second P-well 32b there is a second source implant 38b. Again, in the context of the illustrated embodiment with the N-type semiconductor substrate 12 and the P-well 32, a N⁺ type doping impurity is implanted into the source implants 38. Like the P-well, the specific boundary between the source implant 38 and the P-wells 32 may deviate from the strict boundaries shown in the figure, though a top surface 40 thereof, referred to as the source implant top surface, coincides with the body top surface 16. A given one of the P-wells 32 and the corresponding source implant 38 implanted therein may be collectively referred to as implant regions 39. Thus, the first P-well 32a and the first source implant 38a may be referred to as a first implant region 39a, while the second P-well 32b and the second source implant 38b may be referred to as a second implant region 39b.

A source electrode 42 is disposed on the semiconductor substrate 12, and specifically overlaps the P-well 32 and the source implant 38. The source electrode 42 has a bottom surface 44 that faces and abuts against the source implant top surface 40 and the P-well top surface 36, which coincide with the body top surface 16.

Also formed above the body 14 is a gate oxide layer 46 that extends from the first implant region 39a to the second implant region 39b, across the JFET region 34. The gate oxide layer 46 is defined by a top surface 48 and an opposed bottom surface 50 that faces and abuts against the body top surface 16. As shown, the gate oxide layer 46 partially overlaps the source implant 38 and the inner portions of the P-well 32 that are adjacent to the JFET region 34. A channel region may be defined at the body top surface 16 facing the gate oxide layer 46 between the P-well 32 and the JFET region 34, connecting the source implant 38 thereto. The channel region defines a channel resistance Rₐh that accounts for a substantial proportion of the overall device resistance. The gate oxide layer 46 may be silicon dioxide (SiO₂), though any other suitable material may be substituted.

Partially overlapping and disposed above the gate oxide layer 46 is a gate electrode 52. As shown, the gate electrode 52 does not extend the same length as the gate oxide layer 46. The gate electrode 52 may formed by degenerately doping polysilicon material. Disposed above the gate oxide layer 46 and the gate electrode 52 is an inter-metal dielectric 54. The different source electrodes 42 may be electrically and structurally contiguous with a conductive layer 56 (conventionally aluminum) disposed on the inter-metal dielectric 54. Like the resistance R_{c} associated with the drain electrode 24, there is a similar resistance R_{c} associated with the source electrode 42.

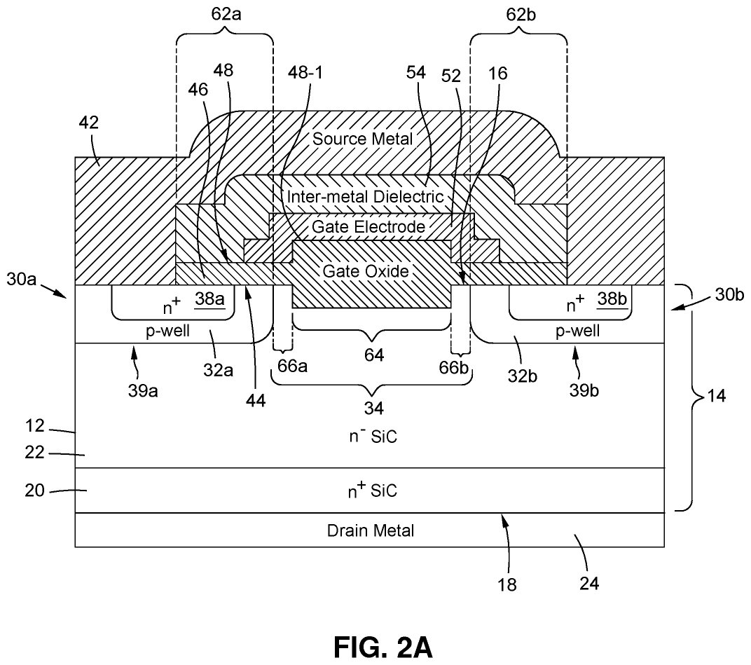

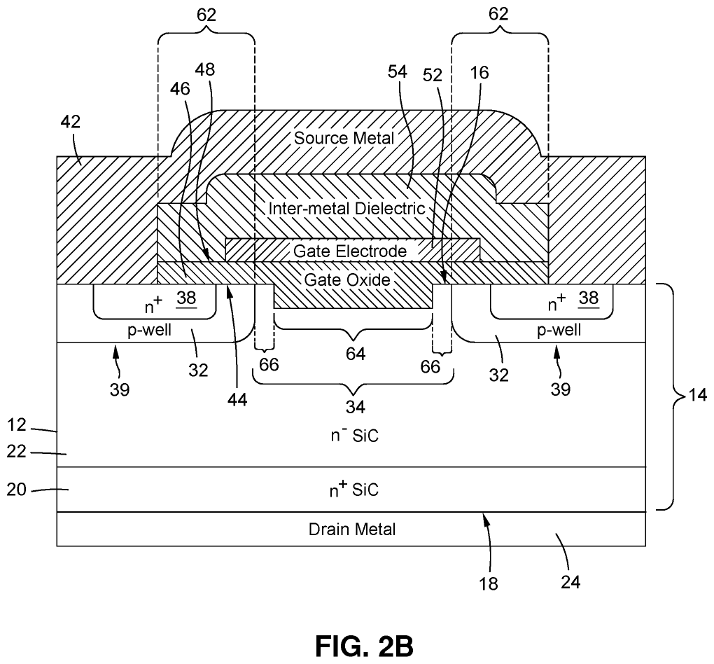

As indicated above, one significant limitation of existing power MOSFETs is the JFET resistance R_{JFET}, and the embodiments of the present disclosure contemplate its reduction, as well as the channel region resistance R_{CH} without increasing the oxide electric field. In one implementation, this involves selectively increasing the thickness of the gate oxide layer 46 in the JFET region 34. With reference to FIG. 2A, an embodiment of the contemplated power MOSFET 60 has some similar structures as the conventional power MOSFET 10 discussed above in the context of FIG. 1. There is the semiconductor substrate 12 characterized by the body 14, which may be defined by the body top surface 16 and the opposed body bottom surface 18. The semiconductor substrate 12 may be silicon carbide that is doped with an N-type doping impurity, more generally referenced herein as the first type doping impurity. The body 14 has a highly N⁺ doped substrate region 20 and a lightly/moderately N⁻ doped drift region 22 above the substrate region 20. The drain electrode 24 is disposed underneath the semiconductor substrate 12.

The body 14 may be generally defined by the left side 30a and an opposed right side 30b. The first implant region 39a is the first P-well 32a implanted into the body 14 from the body top surface 16 toward the left side 30a and the first N⁺ source implant 38a being implanted into the first P-well 32a. Likewise, the second implant region 39b is the second P-well 32b implanted into the body 14 from the body top surface 16 toward the right side 30b and the second N⁺ source implant 38b implanted into the second P-well 32b. Again, the first implant region 39a is laterally separated from the second implant region 39b by a JFET region 34. The gate oxide layer 46 is disposed above the body 14 while extending across the JFET region 34 between the first implant region 39a and the second implant region 39b.

The gate oxide layer 46 may be comprised of multiple sections, though it is understood to be a single structure of unitary construction. In further detail, those portions of the gate oxide layer 46 that partially overlap the P-well 32 and the source implants 38 may be referred to as a channel region 62. There is the bottom surface 44 that faces and abuts against the body top surface 16, and the opposed top surface 48 that abuts against the inter-metal dielectric 54. The lateral extension of the channel regions 62 are limited by the source electrode 42, which is disposed on the body top surface 16 partially overlapping the P-wells 32 and the source implants 38. Located towards the left side 30a of the structure is a left channel region 62a and located towards the right side 30b of the structure is a corresponding right channel region 62b.

Generally centered between the left channel region 62a and the right channel region 62b is an expansion region 64 that extends into the JFET region 34. As will be described in further detail below, the expansion region 64 may be formed by implanting the JFET region 34 with a low penetration ionic species such as aluminum. The expansion region 64 of the gate oxide layer 46 is understood to have a thicker dimension than that of the channel regions 62. Between the channel regions 62 and the expansion region 64, there may be transition region 66 that do not overlap with the P-wells 32 or the source implants 38, while having the same thickness of the channel regions 62. Located toward the left side 30a is a left transition region 66a and located toward the right side 30b is a right transition region 66b. Thus, the expansion region 64 may be referred to as being spaced apart from the implant regions 39, as separated by the dimensions of the transition regions 66 lacking the additional thickness, though ultimately integral with the channel regions 62. However, these transition regions 66 are optional, in that the expansion region 64 may extend to the P-wells 32. The expansion region 64 defines a depth into the JFET region 34 and the bottom plane of the expansion region 64 is generally offset, e.g., deeper, than the bottom plane of either the channel regions 62 or the transition regions 66. In some embodiments, the expansion region 64 may extend above the channel regions 62, such that the entirety of the top surface 48 of the gate oxide layer 46 is not on a single plane. The expansion region 64 may therefore define a raised expansion surface 48-1 that has a planar structure above that of the top surface 48. Regardless, the gate electrode 52 is disposed on top of the gate oxide layer 46, and the corresponding gate electrode 52, the inter-metal dielectric 54, and the source contact 42 may also have raised portions that match the raised contour of the expansion region 64.

Another embodiment of the disclosure contemplates a power MOSFET 60 with an expansion region 64 that extends only into the JFET region 34 and does not define the raised expansion surface 48-1 noted above. Referring now to FIG. 2B, in other respects the second embodiment has the same features as the first embodiment shown in FIG. 2A and described with reference thereto. That is, there is the semiconductor substrate 12 characterized by the body 14 that is defined by the body top surface 16 and the opposed body bottom surface 18. The body 14 has the highly N⁺ doped substrate region 20 and the light/moderately N⁻ doped drift region above the substrate region 20. The drain electrode 24 is disposed underneath the semiconductor substrate 12.

Again, implanted into the top of the body 14 is the P-wells 32, and further implanted therein are the N⁺ source implants 38. Collectively, a given combination of the P-well 32 and the N⁺ source implant 38 are referred to as the implant region 39. With one implant region 39 being separated from another by the JFET region 34, the gate oxide layer 46 is disposed above the body 14 and extend across the JFET region 34 between the same.

The gate oxide layer 46 is understood to be a single structure of unitary construction, though defined by various sections. The channel region 62 are those portions of the gate oxide layer 46 that partially overlap the P-well 32 and the source implants 38. The bottom surface 44 faces and abuts against the body top surface 16, and the opposed top surface 58 abuts against and faces the inter-metal dielectric 54.

Generally centered between the channel regions 62 is the expansion region 64 that extends into the JFET region 34, which may be formed by implanting the JFET region 34 with a low penetration ionic species. The expansion region 64 of the gate oxide layer 46 is understood to have a thicker dimension than that of the channel regions 62. Between the channel regions 62 and the expansion region 64, there may be transition region 66 that do not overlap with the P-wells 32 or the source implants 38, while having the same thickness of the channel regions 62. The expansion region 64 may therefore be referred to as being spaced apart from the implant regions 39, as separated by the dimensions of the transition regions 66 without the additional thickness, though ultimately integral with the channel regions 62. The expansion region 64 defines a depth into the JFET region 34 and the bottom plane of the expansion region 64 is generally offset, e.g., deeper, than the bottom plane of either the channel regions 62 or the transition regions 66. Unlike the first embodiment, however, the expansion region 64 of the second embodiment does not rise above the top surface 48 of the channel region 62. In other words, the top surface of the expansion region 64 is contiguous and coplanar with the top surface 48, such that the top surface 48 of the channel region 62 is the top surface of the entirety of the gate oxide layer 46, including the expansion region 64. This may be achieved with a planarization process following the formation of the gate oxide layer 46 that expands both downwardly and upwardly. As was the case with the first embodiment, the gate electrode 52 is disposed on top of the gate oxide layer 46, together with the inter-metal dielectric 54 and the source electrode 42.

The selectively increased thickness of the gate oxide layer 46 at the expansion region 64 is contemplated to suppress the oxide electric field, and the conventional thickness of the gate oxide layer 46 at the channel regions 62 is understood to maintain low channel resistance R_{CH}. Moreover, a higher doping concentration in the JFET region 34 reduces the JFET resistance R_{JFET}.

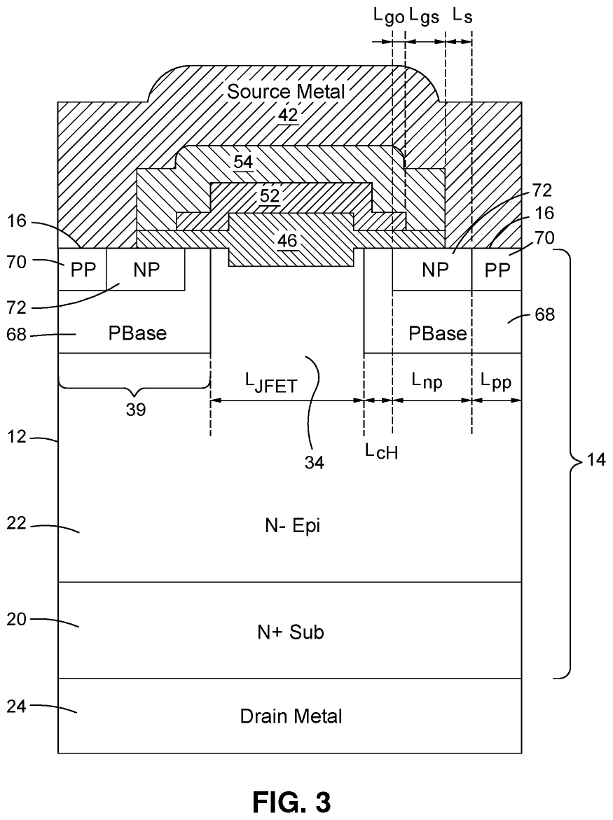

These improvements are based upon quantified estimates of certain dimensional parameters of the power MOSFET, which are shown in a simplified representation of its structure in FIG. 3. Again, the vertically oriented power MOSFET 60 is defined by the semiconductor substrate 12 with the body 14, the substrate region 20, the drift region 22 or N⁻ epitaxial layer, and the implant regions 39. The drain electrode 24 is disposed underneath the substrate region 20. The P-type semiconductor base implant 68, which corresponds to the aforementioned P-well 32, extends a predetermined depth into the body 14 from the body top surface 16. The P-type semiconductor base implant 68 may be contiguous with a more heavily doped P⁺ implant 70 that is adjacent to an N⁺ source implant 72 that generally corresponds to the aforementioned source implant 38. The gate oxide layer 46 is disposed on the body top surface 16, with the gate electrode 52 being disposed on the gate oxide layer 46. The inter-metal dielectric 54 is disposed on the gate electrode 52 and directly over the source implant 72. The source electrode 42 is disposed over the entirety of the foregoing features.

The length Lₚₚ of the P⁺ implant 70 may be 0.5 μm, while the length Lₙₚ of the N⁺ source implant 72 may be 1.25 μm. Based on the foregoing structural details, there is a channel length L_{c}h of 0.5 μm, a length L_{GO} of 0.2 μm that corresponds to the extent of the N⁺ source implant 72 that overlaps and is in contact with the gate oxide layer 46, a length LGs of 0.5 μm that corresponds to the extent of the N⁺ source implant 72 that overlaps and is in contact with the inter-metal dielectric 54, and a length Lₛ of 0.55 μm that corresponds to the extent of the N⁺ source implant 72 that overlaps and is in contact with the source electrode 42. The JFET region 34 has a length L_{JFET} of 1.2 μm, and may be doped at an impurity concentration of 3E17 cm⁻³. According to one embodiment, the gate oxide layer 46 has a thickness that is approximately three times that of conventional implementations. As a consequence, the specific resistance R_{SP} of the JFET region 34 may be reduced by 70%, or 0.116 mil cm², resulting in a specific resistance R_{SP} of the entire power MOSFET 60 being reduced by approximately 10%.

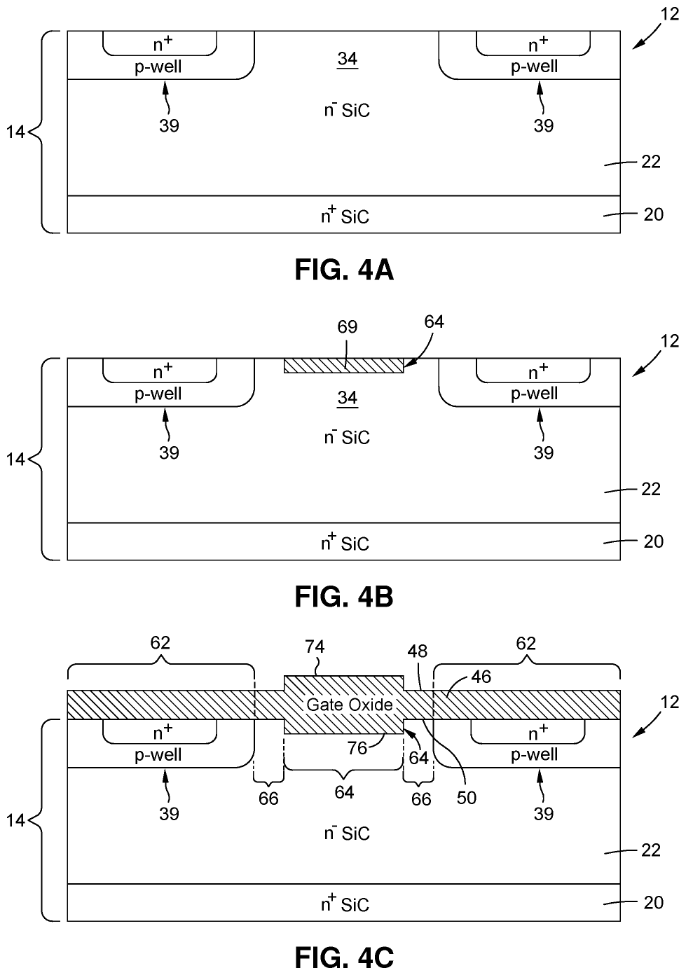

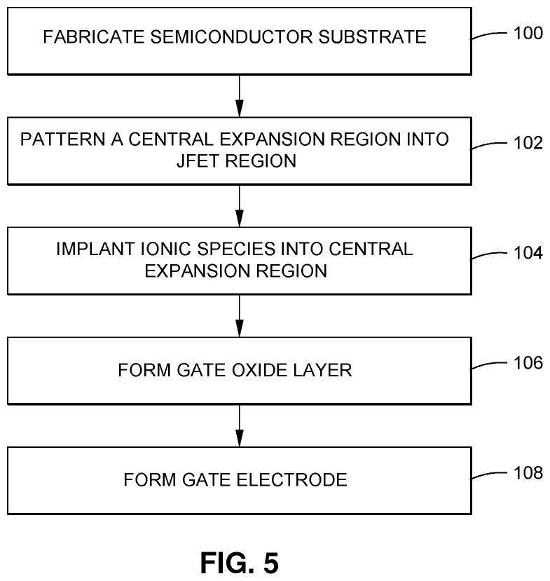

With reference to the cross-sectional views of FIGS. 4A-4C, along with the flowchart of FIG. 5, one exemplary method for fabricating the power MOSFET 60 is illustrated. The method may begin with an initial step 100 of fabricating the semiconductor substrate 12 as shown in FIG. 4A, which is comprised of the body 14 with the substrate region 20 and the drift region 22, and the implant regions 39. Such implant regions 39 include the P-wells 32 that are formed by implanting a P-type doping impurity into the semiconductor substrate 12, as well as the N⁺ source implants 38 that are diffused into the P-wells 32. An activation anneal is applied to the semiconductor substrate 12 with the implant regions 39. The process of growing the semiconductor substrate 12, etching the patterns for forming the drift region 22 and the implant regions 39, and depositing the semiconductor impurities are known in the art, and therefore will not be described in detail.

Thereafter, in a step 102, the expansion region 64 is patterned into the body top surface 16, then in a step 104, a shallow ionic species 69 is implanted therein. The resultant state of the semiconductor substrate 12 following these steps is shown in FIG. 4B. According to one embodiment, the ionic material is a metal such as aluminum, though any other suitable material may be substituted without departing from the scope of the present disclosure. Aluminum may be selected for its low penetration characteristics, such that the expansion region 64 remains relatively shallow without extending deeply into the JFET region 34. However, any other ionic species that have similarly low penetration into the semiconductor body may be utilized. Although conventional processes for forming a gate oxide layer involve growth on a crystalline structure that has been annealed and the implant damage thereto repaired, the present disclosure specifically contemplates the avoidance of such annealing step. It is envisioned that not annealing the expansion region 64 after metal material implantation is for preserving implant damage, as the damaged surface is understood to oxidize at a faster rate.

After the implantation step, the method continues to a step 106 of forming a gate oxide layer 46 on the semiconductor substrate 12, and more generally the entirety of the wafer that is the semiconductor substrate 12. FIG. 4C illustrates the fully formed gate oxide layer 46 being characterized by the expansion region 64 that extends into the JFET region 34, and a thinner channel region 62 on the periphery thereof. As previously discussed, the channel region 62 is understood to be those parts of the gate oxide layer 46 that overlap the implant regions 39, while those parts of the gate oxide layer 46 that have the same thickness as the channel region 62 but directly overlap the JFET region 34 may be referred to as the transition region 66. It is expressly contemplated that the expansion region 64 extends vertically both upward and downward, as shown. However, in alternative embodiments in which the expansion region 64 extends only downward into the JFET region 34, the process may include a step of planarizing the top surface of the expansion region in a manner that forms the contiguous top planar surface as shown in FIG. 2B above. The damage remaining in the unannealed expansion region 64 may be fully consumed by the thermal oxidation process, leaving a thicker oxide layer over the JFET region 34 with good crystalline quality.

The expansion region 64 is defined by a top surface 74 and an opposed bottom surface 76. Further, the channel region 62/transition region 66 are defined by the top surface 48 and the bottom surface 50. The bottom surface 50 of the channel region 62/transition region 66 is vertically offset from the bottom surface 76 of the expansion region 64. Similarly, the top surface 48 of the channel region 62/transition region 66 is vertically offset from the top surface 74 of the expansion region 64. This is understood to result following the thermal gate oxidation process discussed above, which take place in a single step.

The method may proceed to a step 108 of forming the aforementioned gate electrode 52 on to the gate oxide layer 46, along with the dielectric layer 54 and the source electrode 42. However, the specifics of such steps are deemed to be within the purview of those having ordinary skill in the art, and will not be detailed further.

The particulars shown herein are by way of example and for purposes of illustrative discussion of the embodiments of the power metal oxide semiconductor field effect transistor and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A power metal oxide semiconductor field effect device, comprising:
a first semiconductor type body defined by a drift region, one or more second semiconductor type implants, one or more first semiconductor type implant implants within corresponding ones of the one or more second semiconductor type implants, a junction field effect region being defined between a given set of the first semiconductor type implant and the second semiconductor type implant and another set of the first semiconductor type implant and the second semiconductor type implant;
a gate oxide layer spanning a top surface of the semiconductor body across one set of the first and second semiconductor type implants and another set of the first and second semiconductor type implants, channel regions being defined at interfaces of the gate oxide layer and the sets of the first and second semiconductor type implants, the gate oxide layer further defining a central expansion region between the sets of the first and second semiconductor type implants and extending into the junction field effect region;
a gate electrode disposed on the gate oxide layer;
a source electrode at least partially overlapping the first semiconductor type implants and the second semiconductor type implants; and
a drain electrode disposed underneath the semiconductor body.

2. The device of claim 1, wherein the first semiconductor type body is N-doped.

3. The device of claim 2, wherein the second semiconductor type implants are P-wells.

4. The device of claim 2, wherein the first semiconductor type implants are N-type source regions.

5. The device of claim 1, wherein the gate oxide layer and the central expansion region thereof has a unitary structure.

6. The device of claim 1, wherein channel segments of the gate oxide layer are defined by a planar top surface and a planar bottom surface facing and being in abutting contact with a top surface of the first semiconductor type body.

7. The device of claim 6, wherein the channel segments at least partially overlap the first semiconductor type implants and the second semiconductor type implants.

8. The device of claim 6, wherein the central expansion region extends above the planar top surface of the gate oxide layer channel segment.

9. The device of claim 1, wherein the semiconductor body defines a central damaged region having an increased oxidation rate relative to the remainder of the top surface of the semiconductor body.

10. The device of claim 1, wherein:
the first semiconductor type body is a 4H polytype silicon carbide; and
the gate oxide layer is silicon dioxide (SiO₂).

11. A semiconductor device, comprising:
a body defined by a drift region and one or more implant regions, a junction field effect region being defined between one of the implant regions and another one of the implant regions;
a gate oxide layer grown as a single, unitary structure extending across the semiconductor body and at least partially overlapping the implant regions, the gate oxide layer further defining a central expansion region between the implant regions, and extending into the junction field effect region; and
a gate electrode disposed on the gate oxide layer.

12. The semiconductor device of claim 11, wherein the implant region includes a well region implanted with a first doping type impurity, and a source region within the well region implanted with a second doping type impurity.

13. The semiconductor device of claim 11, further comprising:
a source electrode disposed on top of the body, the source electrode facing and being in contact with the implant regions; and
a drain electrode disposed underneath the body.

14. The semiconductor device of claim 11, wherein the gate oxide layer is defined by channel regions corresponding to areas overlapping the implant regions, the channel regions further defining a top surface and a bottom surface.

15. The semiconductor device of claim 14, wherein the bottom surface of the channel region faces and abuts against the body, and a bottom surface of the expansion region is below a plane of the bottom surface of the channel region.

16. The semiconductor device of claim 15, wherein a top surface of the expansion region is above a plane of the top surface of the channel region.

17. A method for fabricating a power metal oxide semiconductor field effect device, comprising:
fabricating a semiconductor substrate with a body defined by a drift region, one or more implant regions, and a junction field effect region between one of the implant regions and another one of the implant regions;
patterning a central expansion region into a center of the junction field effect region;
implanting an ionic species into the central expansion region;
forming a gate oxide layer above a top layer of the semiconductor substrate by thermal oxidation in a single formation step without annealing the implanted ionic species, the gate oxide layer extending into the junction field effect region and defining the central expansion region and channel regions peripheral thereto; and
forming a gate electrode over the gate oxide layer.

18. The method of claim 17, wherein the central expansion region of the gate oxide layer extends above the channel region.

19. The method of claim 17, further comprising:
depositing an inter-metal dielectric on the gate electrode; and
depositing a source metal on the inter-metal dielectric.

20. The method of claim 17, wherein the ionic species is material exhibiting low penetration characteristics into the semiconductor substrate.
